(19) United States
(12) Patent Application Publication
(10) Pub. No.: US 2021/0313326 A1
(43) Pub. Date: Oct. 7, 2021

(54) TRANSISTORS IN A LAYERED ARRANGEMENT

(71) Applicant: QUALCOMM Incorporated, San Diego, CA (US)

(72) Inventors: Kwanyong LIM, San Diego, CA (US); Ye LU, San Diego, CA (US); Lixin GE, San Diego, CA (US)

(21) Appl. No.: 16/840,964

(22) Filed: Apr. 6, 2020

(51) Int. Cl. H01L 27/092; H01L 29/08; H01L 29/06; H01L 29/423; H01L 29/78; H01L 29/786; H01L 21/02; H01L 21/8238; H01L 29/66

(52) U.S. Cl. CPC H01L 27/0922; H01L 27/0924; H01L 29/0847; H01L 29/0673; H01L 29/42392; H01L 29/7851; H01L 29/66742; H01L 29/78696; H01L 21/02603; H01L 21/823821; H01L 21/823814; H01L 21/823807; H01L 29/66795; H01L 29/78618

(57) ABSTRACT

Certain aspects of the present disclosure generally relate to transistors in a layered arrangement. An example semiconductor device generally includes a substrate, an n-type metal-oxide-semiconductor (NMOS) transistor, and a p-type metal-oxide-semiconductor (PMOS) transistor. The NMOS transistor is disposed above the substrate and is a gate-all-around (GAA) field-effect transistor (FET). The PMOS transistor is disposed above the substrate, is a fin field-effect transistor (finFET), and is in a layered arrangement with the NMOS transistor.

### BACKGROUND

### Field of the Disclosure

Certain aspects of the present disclosure generally relate to electronic components and, more particularly, to a layered arrangement for n-type gate-all-around and p-type fin transistors.

### Description of Related Art

A continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices.

Alternative transistor designs to planar transistors have been developed to address various issues with the planar transistor, such as short channel effects as channel lengths in transistors are scaled down. For example, a fin field-effect transistor (FET) (FinFET) has been developed that provides a conducting channel wrapped by a thin silicon “fin,” which forms the gate of the device. FinFET devices may provide faster switching times and higher current densities than planar transistor technology. Gate-all-around (GAA) field-effect transistors (FETs) have enabled a reduction of transistor node sizes below 10 nm. In certain cases, GAA FETs have nanowires, which form the channels, embedded in a gate material disposed between the source and drain. GAA FETs can be designed to have a lower threshold voltage than similar FinFET devices, because GAA FETs have better short channel control. This allows a reduction in supply voltage, which results in a quadratic reduction in power consumption because of voltage scaling.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include a semiconductor device with desirable carrier mobility for n-type and p-type transistors in a complementary arrangement.

Certain aspects of the present disclosure provide a semiconductor device. The semiconductor device generally includes a substrate, an n-type metal-oxide-semiconductor (NMOS) transistor, and a p-type metal-oxide-semiconductor (PMOS) transistor. The NMOS transistor is disposed above the substrate and is a gate-all-around (GAA) field-effect transistor (FET). The PMOS transistor is disposed above the substrate, is a fin field-effect transistor (finFET), and is in a layered arrangement with the NMOS transistor.

Certain aspects of the present disclosure provide a method for fabricating a semiconductor device. The method generally includes forming an NMOS transistor as a GAA FET above a substrate and forming a PMOS transistor as a finFET in a layered arrangement with the NMOS transistor and above the substrate.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1A illustrates a cross-sectional view of an example semiconductor device having transistors in a layered arrangement, in accordance with certain aspects of the present disclosure.

FIG. 1B illustrates a cross-sectional view of another example semiconductor device having transistors in a different layered arrangement, in accordance with certain aspects of the present disclosure.

FIG. 2 illustrates various cross-sectional views of an example semiconductor device, where a p-type metal-oxide-semiconductor (PMOS) transistor is disposed above an n-type metal-oxide-semiconductor (NMOS) transistor in a layered arrangement, in accordance with certain aspects of the present disclosure

FIGS. 3A-8B and 9-27 illustrate various cross-sections of example operations for fabricating a semiconductor device having a PMOS transistor and NMOS transistor in a layered arrangement, in accordance with certain aspects of the present disclosure.

FIGS. 28A-29C illustrate example operations for fabricating superlattice and semiconductor regions, which provide a base stack structure for forming a semiconductor device, in accordance with certain aspects of the present disclosure.

FIG. 30 is a flow diagram of example operations for fabricating a semiconductor device, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to a layered arrangement for an n-type gate-all-around (GAA) transistor and a p-type fin field-effect transistor (FET) (FinFET).

Certain semiconductor devices include GAA transistors to obtain node sizes below 10 nanometers. The carrier mobility characteristics (electron mobility and hole mobility) for n-type and p-type transistors differ between GAA transistors and finFETs. For example, for p-type GAA transistors, the hole mobility may be lower than the hole mobility for p-type finFETs, whereas for n-type GAA transistors, the electron mobility may be higher than the electron mobility for n-type finFETs. In certain cases, the GAA transistors may be used for p-type and n-type transistors throughout a semiconductor device. That is, a homogenous GAA transistor structure may be used for p-type and n-type transistors in certain semiconductor devices. As a result, the p-type GAA transistor for certain semiconductor devices may have a lower-than-desired hole mobility.

Certain aspects of the present disclosure provide a layered arrangement for n-type and p-type transistors where the n-type transistor is a GAA FET and the p-type transistor is a finFET. The layered transistor arrangement described herein may enable desirable electron mobility for the n-type transistor and desirable hole mobility for the p-type transistor. In certain cases, the semiconductor device that employs the layered transistor arrangement may operate with a lower supply voltage, which in turn lowers power consumption, due to the carrier mobilities of the GAA transistors and finFETs.

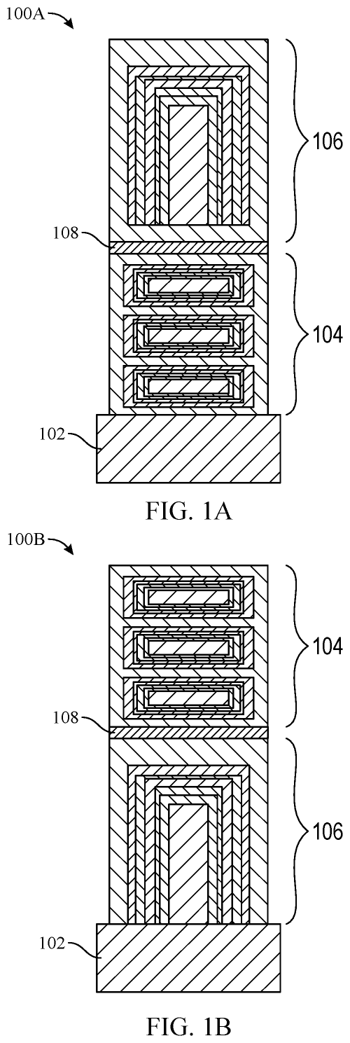

In certain aspects, the n-type transistor may be arranged above the p-type transistor. FIG. 1A illustrates a cross-sectional view of an example semiconductor device 100A, in accordance with certain aspects of the present disclosure. As shown, the semiconductor device 100A includes a substrate 102, an n-type metal-oxide-semiconductor (NMOS) transistor 104, a p-type metal-oxide-semiconductor (PMOS) transistor 106, and a first dielectric layer 108. The NMOS transistor 104 and the PMOS transistor 106 are in a layered arrangement with each other, generally referring to one type of transistor being positioned in a higher layer or level than the other type of transistor, at least in one portion of a semiconductor device (e.g., a semiconductor die). In certain aspects, certain portions (e.g., source and/or drain regions) of the transistors 104, 106 may be separated by a single layer of dielectric material in the layered arrangement as further described herein. In this example, the PMOS transistor 106 is arranged above the NMOS transistor 104.

The substrate 102 may be a portion of, for example, a semiconductor wafer such as a silicon wafer. The substrate 102 may serve as a base material on which the various elements of the semiconductor device 100A are formed. A dielectric region (not shown) may be disposed in the substrate as a shallow trench isolation (STI) region configured to electrically isolate—or at least increase the electrical isolation of—various electrical devices disposed above the substrate 102.

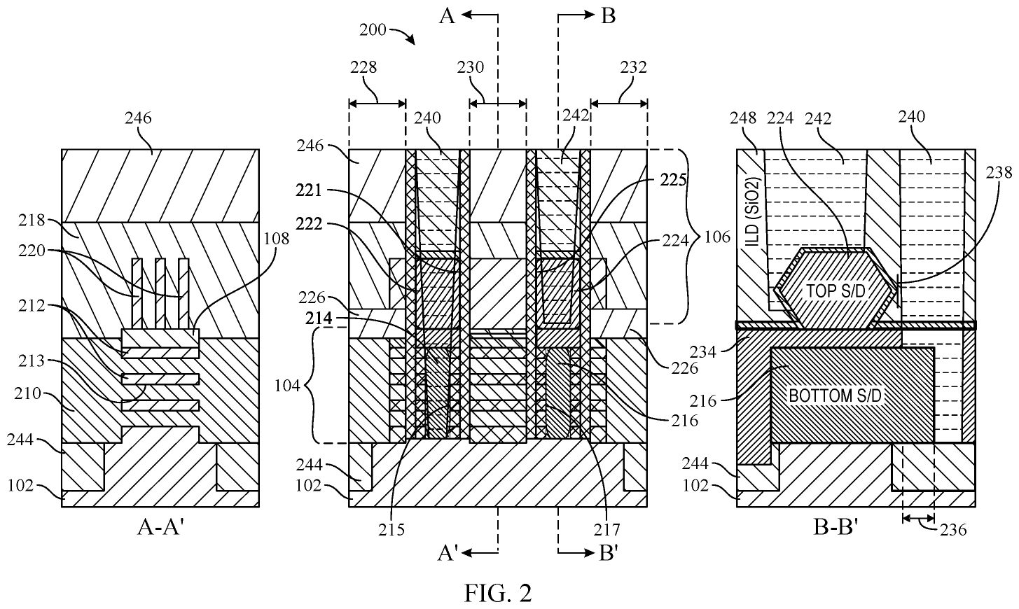

Disposed above the substrate 102, the NMOS transistor 104 is a GAA FET, for example, including a stacked structure with channel regions (such as nanowires, nanoslabs, or nanosheets) intersecting a gate region, as further described herein with respect to FIG. 2. As a GAA FET, the NMOS transistor 104 may have a desirable electron mobility.

Also disposed above the substrate 102, the PMOS transistor 106 is a finFET, for example, having one or more semiconductor fin structures and a gate region surrounding a portion of at least one of the semiconductor fin structures, as further described herein with respect to FIG. 2. As a finFET, the PMOS transistor 106 may have a desirable hole mobility.

The first dielectric layer 108 may include an electrical insulating material, such as silicon dioxide (SiO₂) or silicon nitride (Si₃N₄). The first dielectric layer 108 may electrically isolate the NMOS transistor 104 from the PMOS transistor 106. In aspects, the first dielectric layer 108 is disposed between the NMOS transistor 104 and the PMOS transistor 106.

In other aspects, the n-type transistor may be arranged above the p-type transistor. FIG. 1B illustrates a cross-sectional view of another example semiconductor device 100B, in accordance with certain aspects of the present disclosure. As shown, the NMOS transistor 104 is arranged above the PMOS transistor 106.

FIG. 2 illustrates various cross-sectional views of an example semiconductor device 200, in accordance with certain aspects of the present disclosure. FIG. 2 illustrates a base cross-section with counterpart cross-sections along lines A-A′ and B-B′ of the base cross-section. In this example, the NMOS transistor 104 is arranged below the PMOS transistor 106. In aspects, the NMOS transistor 104 includes a gate region 210, channel regions 212, a source region 214, and a drain region 216. As shown, the gate region 210 and channel regions 212 are in a layered arrangement, where a portion of the gate region 210 is disposed between each of the channel regions 212. The channel regions 212 may include semiconductor nanowires, nanoslabs, or nanosheets that intersect the gate region 210. In aspects, the gate region 210 may surround lateral surfaces 213 of the channel regions 212. For instance, across the second portion 230 of the semiconductor 200, the gate region 210 may engage certain lateral surfaces (e.g., the lateral surface 213) of the channel regions 212, and the source and drain regions 214, 216 may engage other surfaces (e.g., the ends 215, 217) of the channel regions 212.

In aspects, the gate region 210 may include various layers of conductive materials and/or dielectric materials (not shown). In aspects, the conductive materials may include various work function metals including titanium nitride (TiN), aluminum (Al), tantalum nitride (TaN), titanium aluminide (TiAl), tungsten (W), etc. In aspects, the dielectric materials may include a dielectric material (e.g., hafnium dioxide (HfO₂), zirconium dioxide (ZrO₂), and/or titanium dioxide (TiO₂)) with a dielectric constant (κ) higher than silicon dioxide (SiO₂) (e.g., κ=3.9). In certain cases, the dielectric material of the gate regions 210 may be referred to as a high-κ dielectric.

The channel regions 212 may include a semiconductor material, such as silicon (Si) or silicon germanium (SiGe). In certain aspects, the semiconductor material of the channel regions 212 may be an n-type semiconductor material (e.g., via doping).

The source and drain regions 214, 216 intersect the channel regions 212, such that across the second portion 230 of the semiconductor device 200, the source region may be coupled to the first ends 215 of the channel regions 212, and the drain region 216 may be coupled to the second ends 217 of the channel regions 212. In aspects, the source and drain regions 214, 216 may be electrically isolated from the gate region 210. In aspects, a portion of the gate region 210 and a portion of the channel regions 212 (e.g., across the second portion 230) are disposed between the source region 214 and drain region 216. In certain aspects, the source region 214 and drain region 216 may include a doped (e.g., n+), epitaxially grown semiconductor structure.

In aspects, the PMOS transistor 106 includes a gate region 218, channel regions 220, a source region 222, and a drain region 224. In aspects, the channel regions 220 may be semiconductor fin structures, and the gate region 218 may surround a substantial portion of each of the semiconductor fin structures of the channel regions 220.

In aspects, the gate region 218 may include various layers of conductive materials and/or dielectric materials (not shown). In aspects, the conductive materials may include various work function metals including titanium nitride (TiN), aluminum (Al), tantalum nitride (TaN), titanium aluminide (TiAl), tungsten (W), etc. In aspects, the dielectric materials of the gate region 218 may include a high-κ dielectric.

The channel regions 220 may include a semiconductor material, such as silicon (Si) or silicon germanium (SiGe). In certain aspects, the semiconductor material of the channel regions 220 may be a p-type semiconductor material (e.g., via doping).

The source and drain regions 222, 224 intersect the channel regions 220, such that across the second portion 230 of the semiconductor device 200, the source region 222 may be coupled to first lateral surfaces 221 of the channel regions 220, and the drain region 224 may be coupled to a second lateral surfaces 225 of the channel regions 220. In aspects, a portion of the gate region 218 and a portion of the channel regions 220 (e.g., across the second portion 230) are disposed between the source region 222 and drain region 224. In certain aspects, the source region 222 and drain region 224 may include a doped (e.g., p+), epitaxially grown semiconductor structure.

Various electrical insulators (such as dielectric regions and/or dielectric layers including silicon dioxide or silicon nitride) may be disposed between various portions of the NMOS transistor 104 and PMOS transistor 106. In certain aspects, the first dielectric layer 108 is disposed between the channel regions 212 of the NMOS transistor 104 and the channel regions 220 of the PMOS transistor 106, such that the first dielectric layer 108 electrically isolates the channel regions 212 of the NMOS transistor 104 from the channel regions 220 of the PMOS transistor 106.

In aspects, one or more second dielectric layers 226 may be disposed between the gate region 210 of the NMOS transistor 104 and the gate region 218 of the PMOS transistor 106, such that at least a portion of the gate region 210 of the NMOS transistor 104 is electrically isolated from at least a portion of the gate region 218 of the PMOS transistor 106. For example, the second dielectric layers 226 may be disposed between the gate regions 210, 218 across a first portion 228 and third portion 232 of the semiconductor device 200.

In certain aspects, another portion of the gate region 210 of the NMOS transistor 104 may be electrically coupled to another portion of the gate region 218 of the PMOS transistor 106, for example, as depicted in the cross-section A-A′ of FIG. 2. In other words, there may be no second dielectric layer disposed between the gate regions 210, 218, for example, across a second portion 230, which is between the first portion 228 and third portion 232 of the semiconductor device 200. In certain cases, the NMOS transistor 104 and PMOS transistor 106 may form a complementary metal-oxide-semiconductor (CMOS) circuit, such as an inverter or other suitable CMOS circuits where the gates of the CMOS transistors are electrically coupled together.

In certain aspects, one or more first dielectric regions 234 may be disposed between the source region 214 or drain region 216 of the NMOS transistor 104 and the source region 222 or drain region 224 of the PMOS transistor 106. For instance, one of the first dielectric regions 234 may electrically isolate the drain region 216 from the drain region 224, for example, as depicted in the cross-section B-B′. In aspects, another of the first dielectric regions 234 (not shown) may be disposed between the source region 214 of the NMOS transistor 104 and the source region 222 of the PMOS transistor 106.

In aspects, a second dielectric region 244 may be disposed in the substrate 102 as the STI region, which electrically isolates various electrical devices (such as the NMOS transistor 104) coupled to the substrate 102. In aspects, a third dielectric region 246 may be disposed above the gate region of the transistor, which is disposed above the other transistor in the layered arrangement. For instance, the third dielectric region 246 may be disposed above the gate region 218 of the PMOS transistor 106. In certain aspects, the third dielectric region 246 may be a self-aligned contact for insulating a portion of the gate region 218 from the conductive materials of the terminals 240, 242. In aspects, a fourth dielectric region 248 may be arranged adjacent to and above the source and drain regions 222, 224 of the PMOS transistor, for example, as depicted in the cross-section B-B′. The fourth dielectric region 248 may electrically isolate the terminals 240, 242 from each other.

In aspects, a portion of a source region or drain region of the transistor, which is disposed below the other transistor in the layered arrangement, may extend beyond a surface of a source region or drain region of the other transistor. For instance, as depicted in the cross-section B-B′, the portion 236 of the drain region 216 of the NMOS transistor 104 may extend beyond the surface 238 of the drain region 224 of the PMOS transistor 106. The extended portion of the source region or drain region may enable the transistor, which is disposed below the other transistor in the layered arrangement, to electrically couple to various electrically conductive terminals 240, 242.

The terminals 240 may be electrically coupled to the gate region 210, source region 214, and drain region 216 of the NMOS transistor 104, whereas the terminals 242 may be electrically coupled to the gate region 218, source region 222, and drain region 224 of the PMOS transistor 106. In aspects, the terminals 240, 242 may be electrically coupled to various conductive wiring (e.g., metal layers and/or conductive vias) disposed above and/or below the transistors 104, 106.

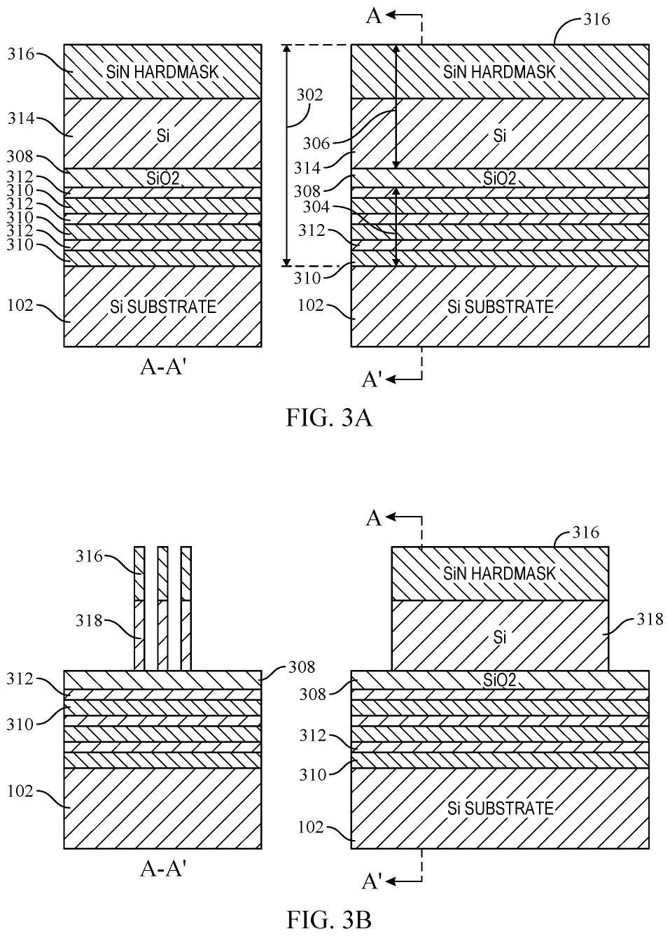

FIGS. 3A-8B and 9-27 illustrate various cross-sections of example operations for fabricating a semiconductor device having a PMOS transistor and NMOS transistor in a layered arrangement, in accordance with certain aspects of the present disclosure. Each of the FIGS. 3A-8B and 9-27 illustrates a base cross-section with counterpart cross-section(s) along lines A-A′ or B-B′ of the base cross-section. The operations may be performed by a semiconductor fabrication facility, for example. The operations may include various front-end-of-line (FEOL) fabrication processes, when electrical devices (e.g., transistors) are patterned on a substrate (e.g., the substrate 102), and/or various back-end-of-line (BEOL) fabrication processes, when the electrical devices are electrically interconnected.

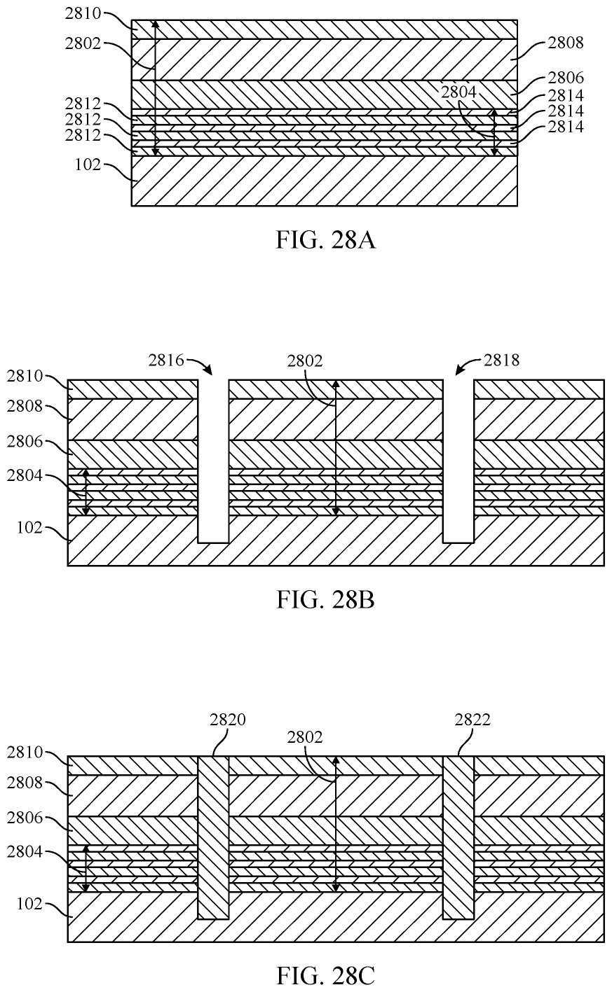

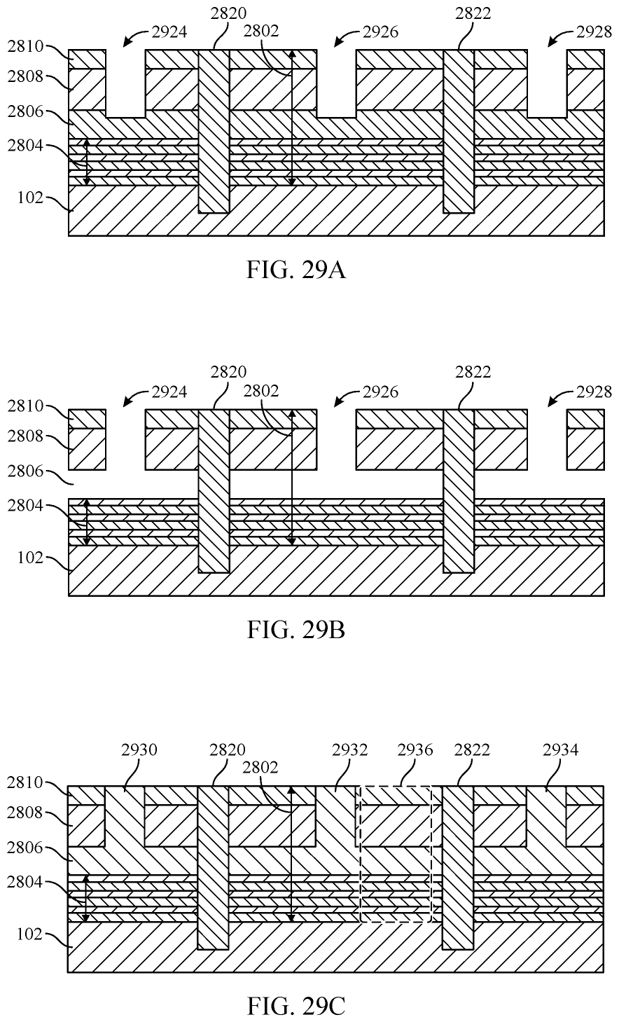

As illustrated in FIG. 3A, a first stack structure 302 may be formed above the substrate 102, for example, as further described herein with respect to FIGS. 28A-29C. In certain cases, a boule of a semiconductor (e.g., silicon) may be formed and sliced into individual wafers, and the substrate 102 may be a portion of a semiconductor wafer, such as a silicon wafer.

The first stack structure 302 may include various layers of dielectrics and semiconductor materials. In certain cases, the first stack structure 302 may include a first portion 304, a second portion 306, and a first dielectric layer 308 disposed between the first portion 304 and second portion 306. In certain cases, the first portion 304 of the first stack structure 302 includes alternating layers of a first semiconductor material 310 and layers of a second semiconductor material 312. The NMOS transistor 104 may be formed from the first portion 304 of the first stack structure 302. In certain cases, the first portion 304 of the first stack structure may also be referred to as a nanoslab. In aspects, the first semiconductor material 310 may include silicon germanium (SiGe), and the second semiconductor material 312 may include silicon (Si). In aspects, each of the layers of the first semiconductor material may be formed via a chemical vapor deposition (CVD) on an underlying layer of silicon, where the CVD produces a thin film of SiGe on the underlying silicon. In aspects, each of the layers of the first semiconductor material 310 may have a height (e.g., 10 nm) that is greater than the height (e.g., 5 nm) of the layers of the second semiconductor material 312. In aspects, the various semiconductor layers of the first stack structure 302 may be epitaxially grown.

The second portion 306 of the first stack structure 302 may include a third semiconductor layer 314 and a first hardmask layer 316. The third semiconductor layer 314 may include a semiconductor material such as silicon. The PMOS transistor 106 may be formed from the third semiconductor layer 314, as further described herein. The first hardmask layer 316 may include silicon nitride (Si₃N₄). The first hardmask layer 316 may serve as a patterning mask to form semiconductor fin structures as depicted in FIG. 3B.

As shown in FIG. 3B, portions of the semiconductor layer 314 may be removed. For example, an etching process (wet etching and/or dry etching), may be used to selectively remove portions of the semiconductor layer 314 to form the semiconductor fin structures 318. In aspects, the first hardmask layer 316 may be used to pattern the arrangement of the semiconductor fin structures 318. That is, portions of the first hardmask layer 316 may be removed in a pattern overlaying the arrangement of the semiconductor fin structures 318.

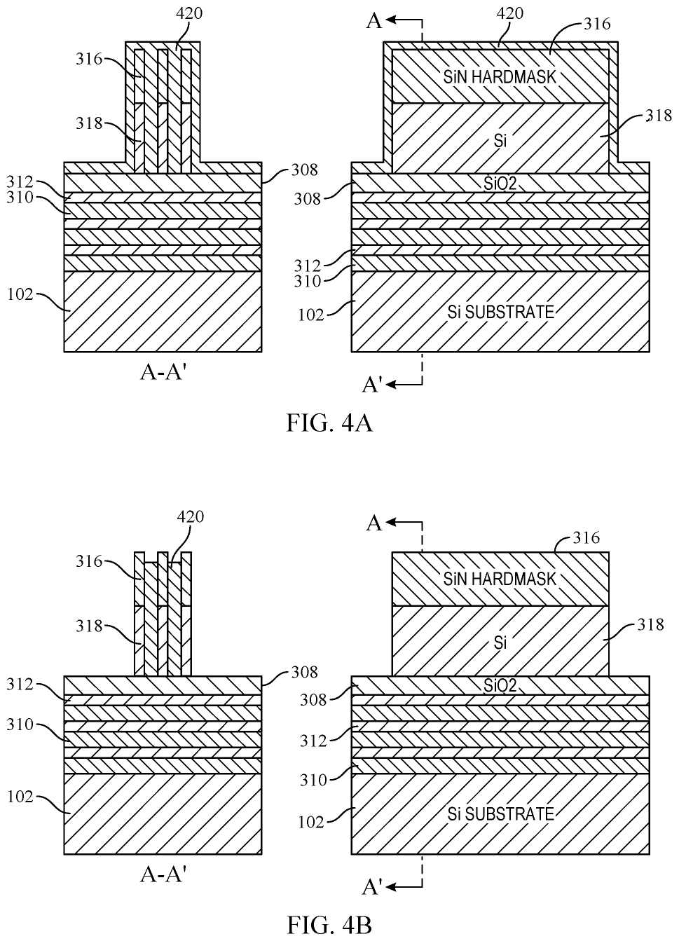

Referring to FIG. 4A, a first dummy layer 420 may be formed above the first dielectric layer 308, semiconductor fin structures 318, and the remaining portions of the first hardmask layer 316. The first dummy layer 420 may also be formed in-between the semiconductor fin structures 318. That is, the first dummy layer 420 may be disposed between the semiconductor fin structures 318. In aspects, the first dummy layer 420 may include a semiconductor material, such as amorphous silicon germanium. The first dummy layer 420 may serve as a temporary filler between the semiconductor fin structures 318 as other operations are performed to form the semiconductor device.

As shown in FIG. 4B, portions of the first dummy layer 420 are removed, such that the remaining portions of the first dummy layer 420 are disposed between the semiconductor fin structures 318. In certain cases, an etching process may be used to remove the portions of the first dummy layer 420.

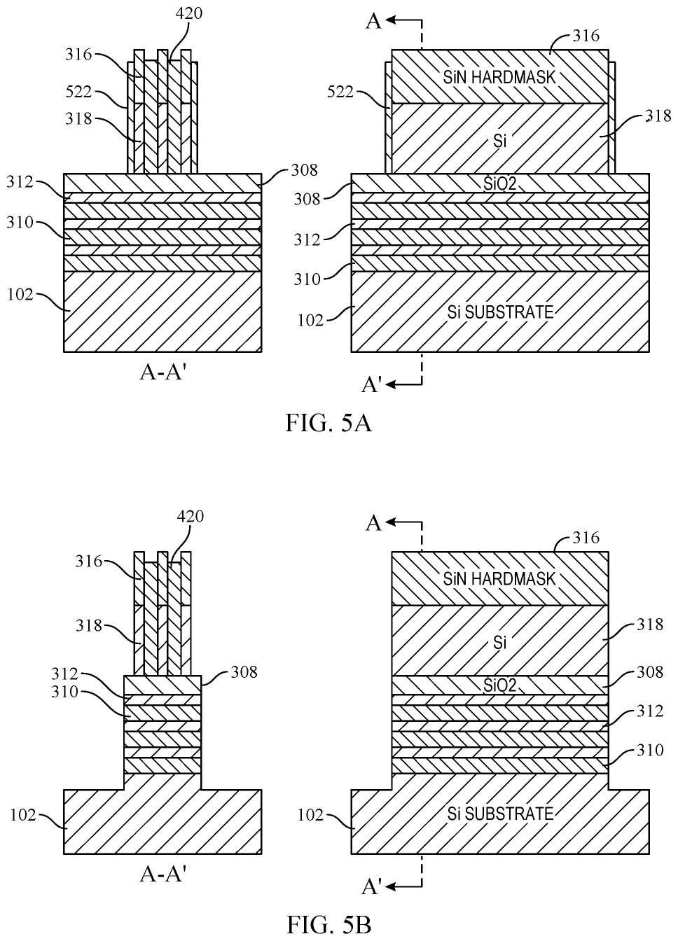

As illustrated in FIG. 5A, an oxide spacer 522 may be formed adjacent to the semiconductor fin structures 318. In certain aspects, the oxide spacer 522 may include silicon oxide. The oxide spacer 522 may serve as a temporary layer that protects the semiconductor fin structures 318 as the first portion 304 of the first stack structure 302 is patterned for the GAA transistor (e.g., nanoslab patterning is performed).

Referring to FIG. 5B, the nanoslab patterning is performed. For instance, portions of the alternating layers of the first semiconductor material 310 and second semiconductor material 312 are removed, for example, using an etching process. In aspects, the oxide spacer 522 is also removed.

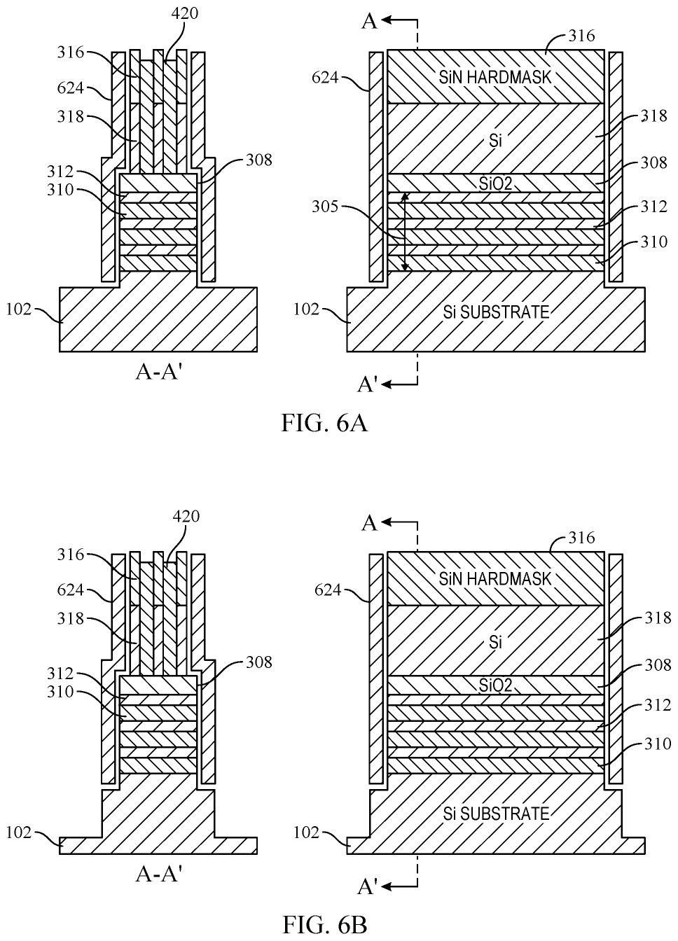

Referring to FIG. 6A, a hardmask liner 624 is formed adjacent to the semiconductor fin structures 318. In aspects, the hardmask liner 624 may include silicon nitride (Si₃N₄). The hardmask liner 624 may protect the semiconductor fin structures 318 and the nanoslab 305, which includes the alternating layers of the first semiconductor material 310 and second semiconductor material 312, from oxidation as the STI region is formed. The hardmask liner 624 may serve as a patterning mask to form the STI region in the substrate 102. As shown in FIG. 6B, portions of the substrate 102 are removed, for example, using an etching process.

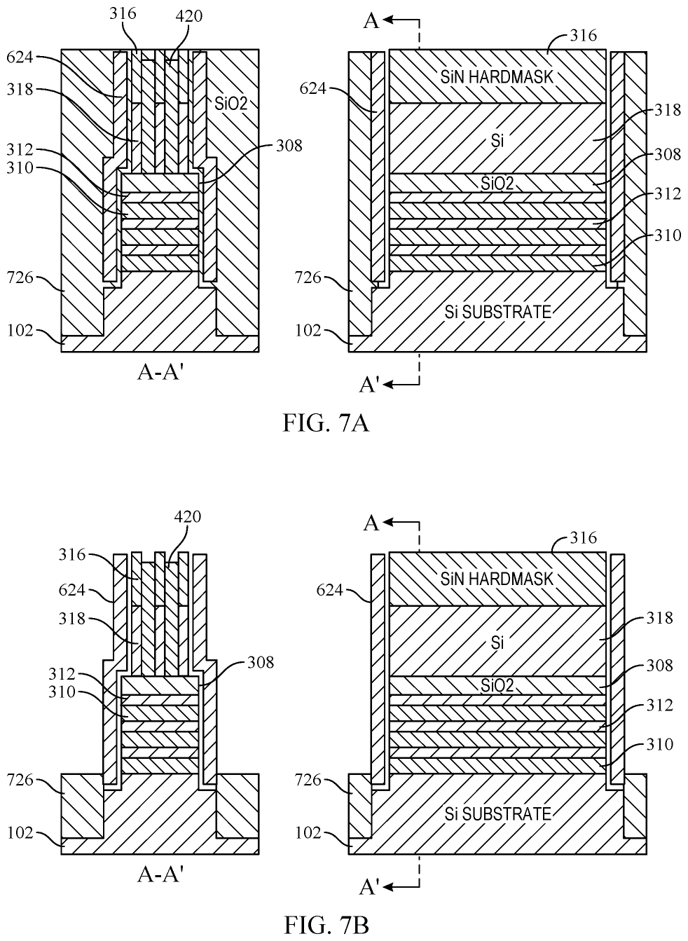

Referring to FIG. 7A, a first dielectric region 726 is formed adjacent to the hardmask liner 624 and above the substrate 102. The first dielectric region 726 may include a dielectric material such as silicon dioxide. As illustrated in FIG. 7B, a portion of the first dielectric region 726 may be removed leaving an STI region disposed above and adjacent to portions of the substrate 102. A planarization process (e.g., a chemical mechanical planarization (CMP) process) may be performed to remove a portion of the first dielectric region 726 disposed above the first hardmask layer 316.

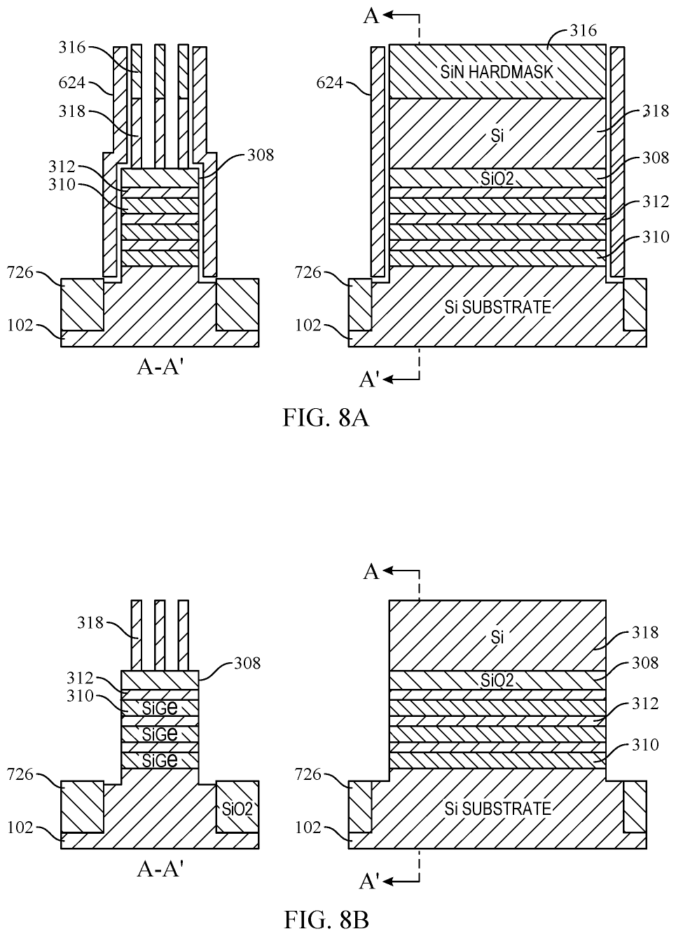

As depicted in FIG. 8A, the remaining portion of the first dummy layer 420 is removed from between the semiconductor fin structures 318, for example, using an etching process to selectively remove the first dummy layer 420. As illustrated in FIG. 8B, the first hardmask layer 316 and hardmask liner 624 are removed, for example, using an etching process.

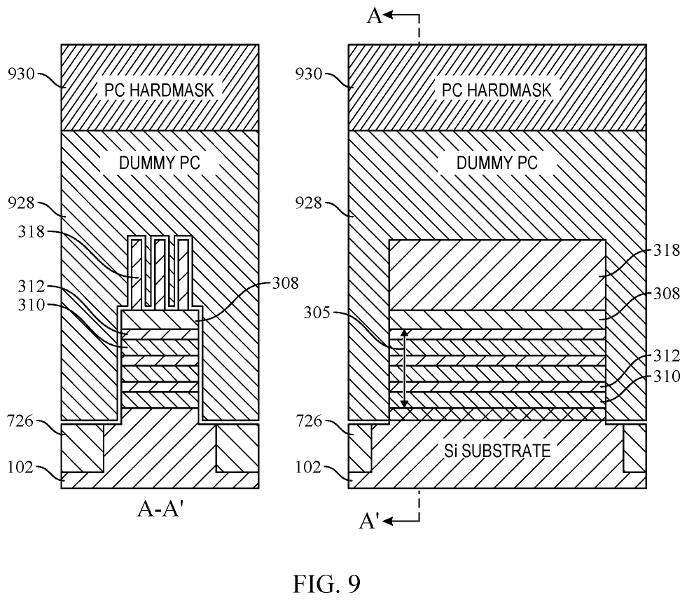

Referring to FIG. 9, a second dummy layer 928 is formed between and adjacent to the semiconductor fin structures 318. The second dummy layer 928 is also formed adjacent to the nanoslab 305 and above the first dielectric region 726. In aspects, the second dummy layer 928 may include a polycrystalline silicon material. A second hardmask layer 930 is formed above the second dummy layer 928. In aspects, the second hardmask layer 930 may include silicon nitride. The hardmask layer 930 may serve as a patterning mask to form cavities in the second dummy layer 928 for source and drain regions of the transistors and terminals.

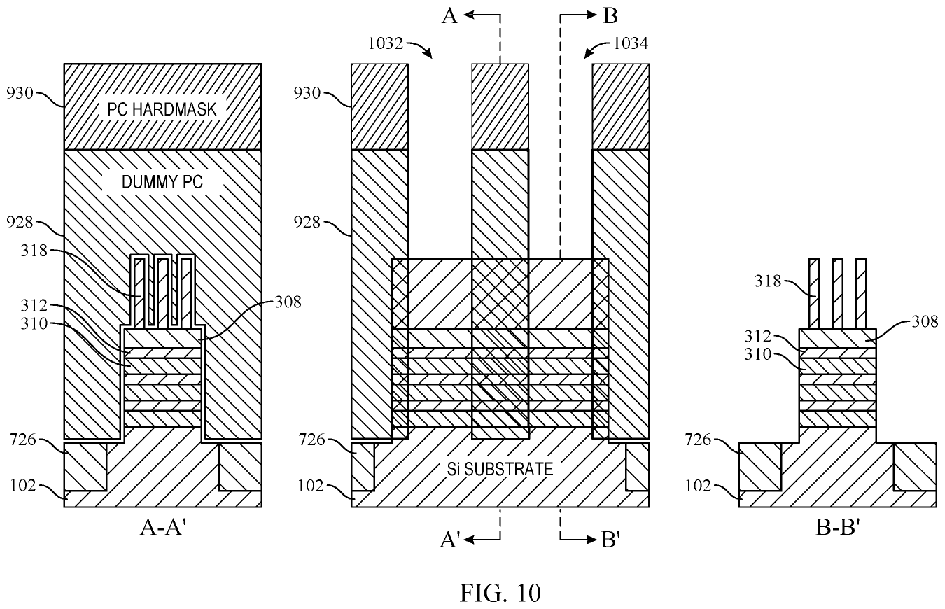

As illustrated in FIG. 10, portions of the second dummy layer 928 are removed, for example, using an etching process. In aspects, the etching process may form cavities 1032, 1034 in the second dummy layer 928, and the cavities 1032, 1034 may serve as molds for the source and drain regions of the transistors.

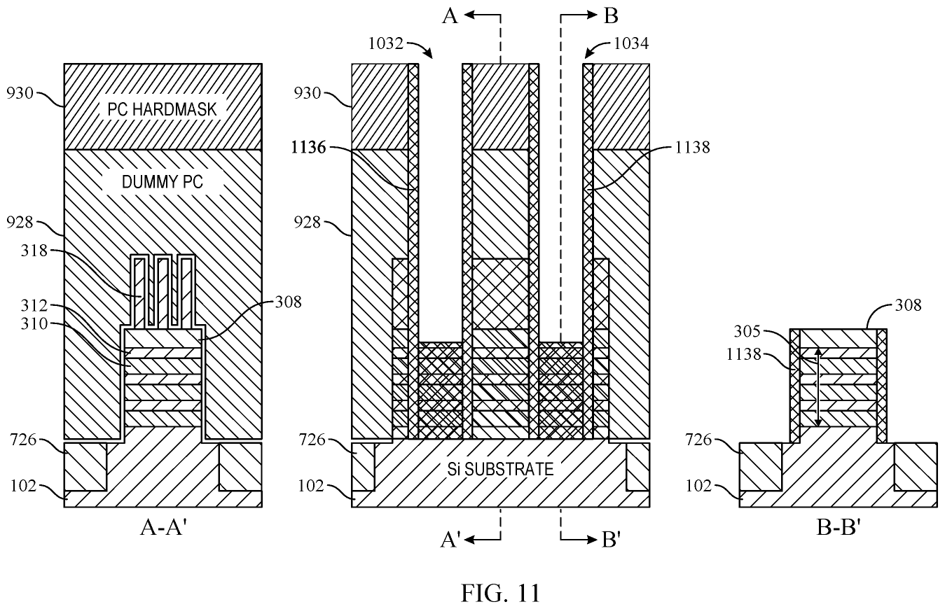

As depicted in FIG. 11, gate spacers 1136, 1138 may be formed in the cavities 1032, 1034, such that the gate spacers 1136, 1138 form an interior layer inside the cavities 1032, 1034. In aspects, the gate spacers 1136, 1138 may cover portions of the semiconductor fin structures, the first dielectric layer, and the nanoslab 305. The cavities 1032, 1034 may be extended, such that portions of the semiconductor fin structures 318 and/or the first dielectric layer 308 are removed, for example, using an etching process. In aspects, a portion of the first dielectric layer 308 may remain disposed above the nanoslab 305, for example, as depicted in the cross-section B-B′ of FIG. 11. Following the etching process, the gate spacers 1136, 1138 may also be disposed adjacent to the nanoslab 305, for example, as depicted in the cross-section B-B′ of FIG. 11. In aspects, the gate spacers 1136, 1138 may include a hardmask material, such as silicon nitride.

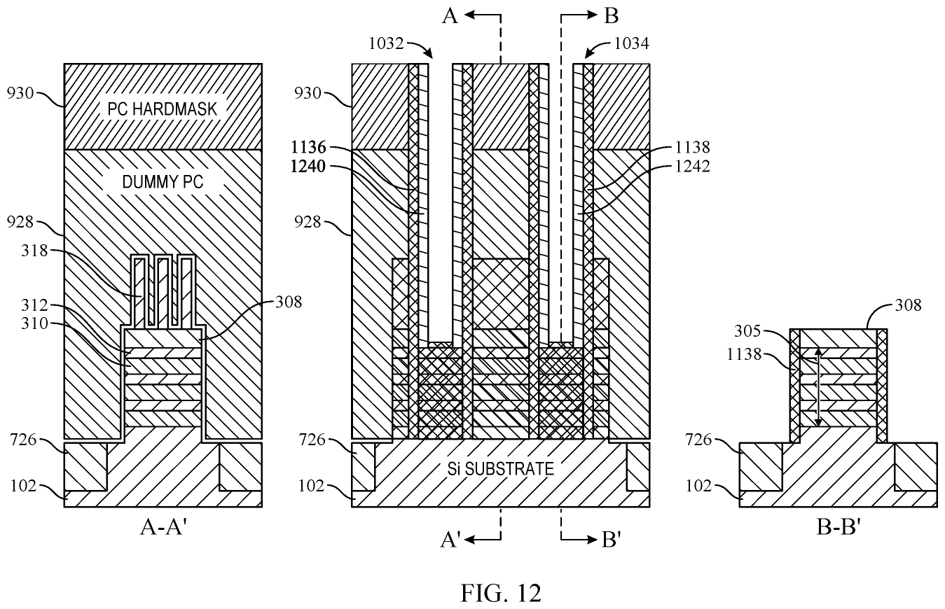

Referring to FIG. 12, sidewall spacers 1240, 1242 may be formed in the cavities 1032, 1034, such that the sidewall spacers 1240, 1242 are disposed adjacent to the gate spacers 1136, 1138. In aspects, the sidewall spacers 1240, 1242 may include a dielectric material, such as silicon dioxide. The sidewall spacers 1240, 1242 may protect the sidewall of the PMOS transistor as the cavities are extended into the nanoslab 305 to form molds for the source and drain regions of the NMOS transistor.

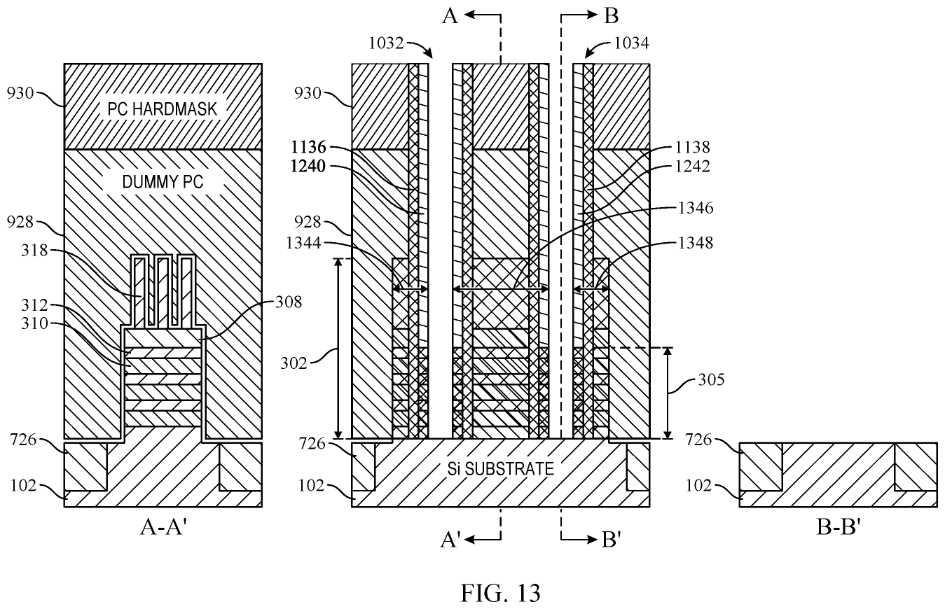

As illustrated in FIG. 13, the cavities 1032, 1034 may be extended, such that portions of the nanoslab 305 are removed, for example, using an etching process. The extended portion of the cavities 1032, 1034 may provide a mold for forming source and drain regions of the NMOS transistor. In aspects, as the cavities 1032, 1034 intersect portions of the first stack structure 302, the first stack structure 302 may be partitioned into a second stack structure 1344, a third stack structure 1346, and a fourth stack structure 1348.

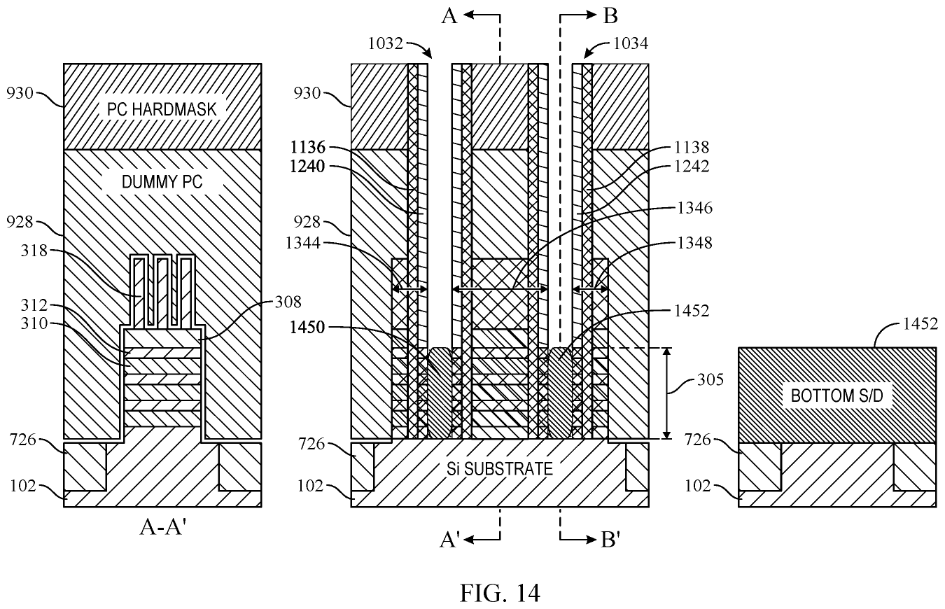

As depicted in FIG. 14, a source region 1450 for the NMOS transistor is formed in the cavity 1032 and between the second stack structure 1344 and third stack structure 1346. A drain region 1452 for the NMOS transistor is also formed in the cavity 1034 and between the third stack structure 1346 and fourth stack structure 1348. The source and drain regions 1450, 1452 may extend along lateral surfaces of the nanoslabs 305 of the second, third, and fourth stack structures 1344, 1346, 1348. In certain cases, an etching process may be performed to ensure the source and drain regions 1450, 1452 do not extend above the first dielectric layer 308. In aspects, the source and drain regions 1450, 1452 may include a doped (e.g., n+) semiconductor structure, which may be epitaxially grown or deposited in the cavities 1032, 1034.

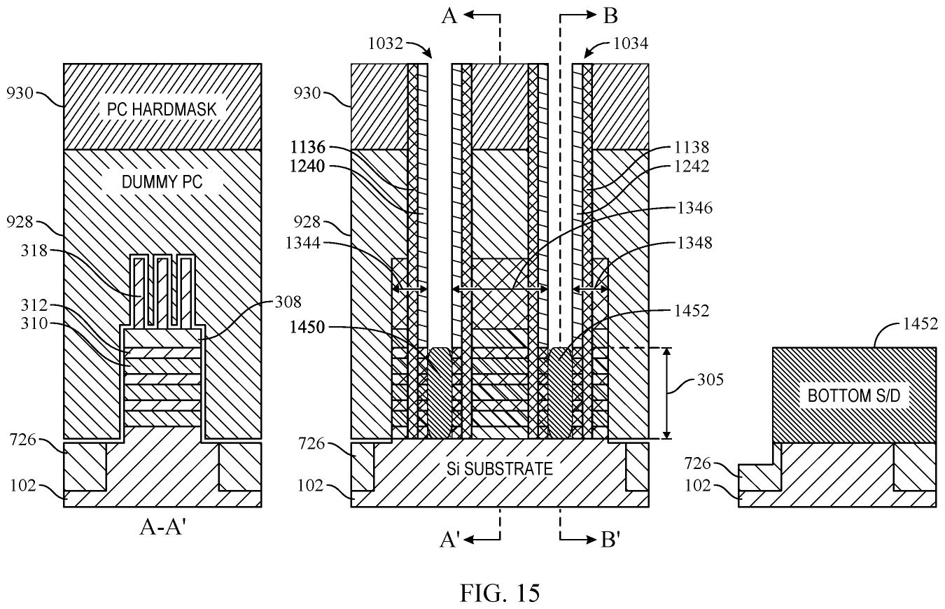

As shown in FIG. 15, in certain cases, a portion of the source region 1450 and/or drain region 1452 may be removed. For example, the cross-section B-B′ illustrates the drain region 1452 with a portion removed. In aspects, the removed portion(s) may facilitate electrical routing (not shown) adjacent to the source or drain regions 1450, 1452.

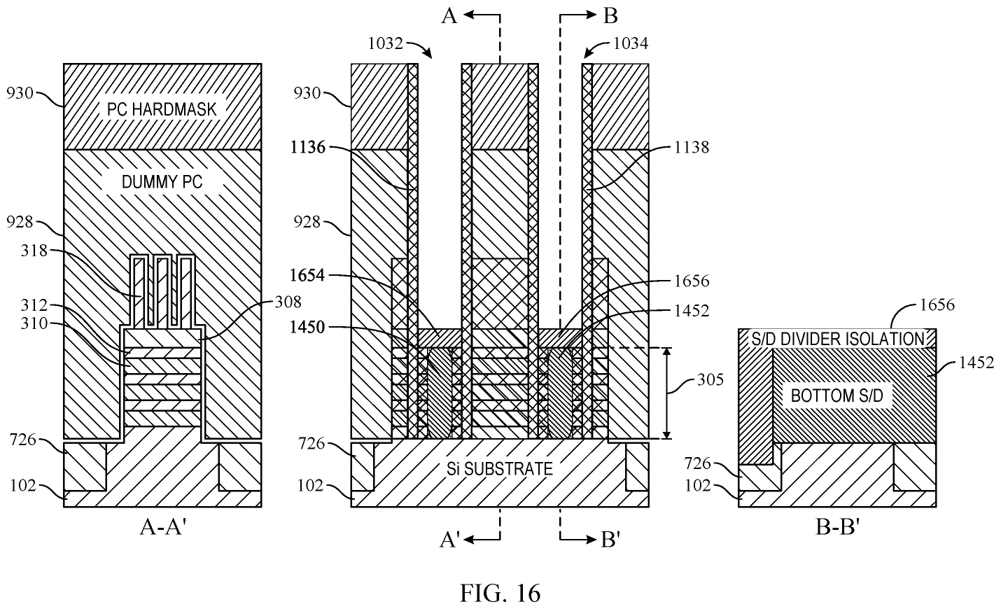

Referring to FIG. 16, one or more second dielectric regions 1654, 1656 may be formed above the source and drain regions 1450, 1452 in the cavities 1032, 1034. The second dielectric regions 1654, 1656 be adjacent to or engage the source and drain regions 1450, 1452, for example, as depicted in the cross-section B-B′. The one or more second dielectric regions 1654, 1656 may electrically isolate the source and drain regions 1450, 1452 from the other source and drain regions. In aspects, the one or more second dielectric regions 1654, 1656 may correspond to the first dielectric region 234 of FIG. 2. In certain cases, the sidewall spacer 1240, 1242 may also be removed from the cavities 1032, 1034, for example, using an etching process.

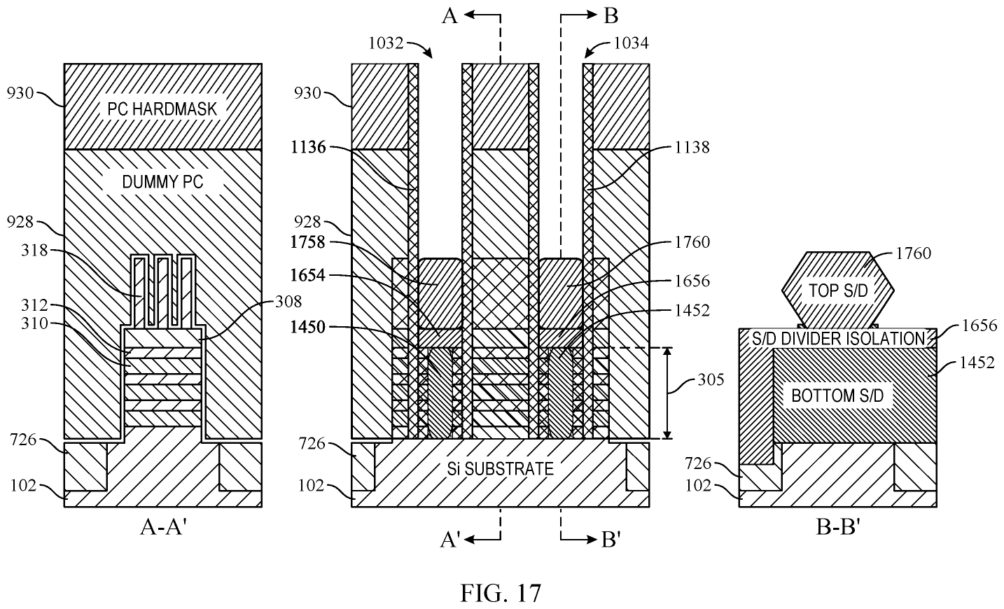

As illustrated in FIG. 17, a source region 1758 for the PMOS transistor is formed in the cavity 1032 and between the second stack structure 1344 and third stack structure 1346. A drain region 1760 for the PMOS transistor is also formed in the cavity 1034 and between the third stack structure 1346 and fourth stack structure 1348. The source and drain regions 1758, 1760 may be disposed above the second dielectric regions 1654, 1656.

The source and drain regions 1758, 1760 may extend along lateral surfaces of the semiconductor fin structures 318 of the second, third, and fourth stack structures 1344, 1346, 1348. In certain cases, an etching process may be performed to remove portions of the source and drain regions 1758, 1760. In aspects, the source and drain regions 1758, 1760 may include a doped (e.g., p+) semiconductor structure, which may be epitaxially grown or deposited in the cavities 1032, 1034.

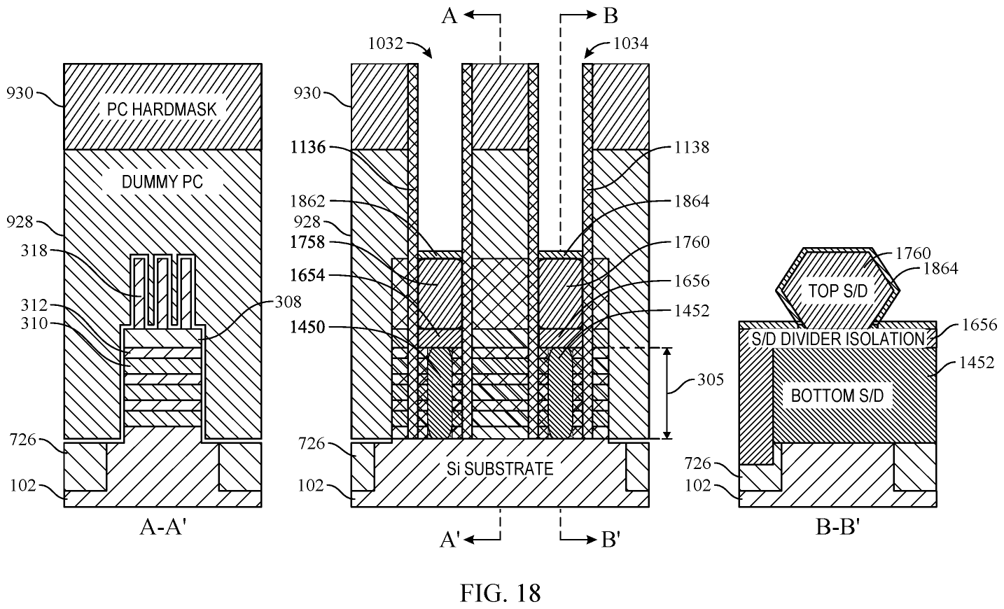

As depicted in FIG. 18, contact etch stop layers (CESLs) 1862, 1864 may be formed adjacent to the source and drain regions 1758, 1760 and the second dielectric regions 1654, 1656 in the cavities 1032, 1034. In certain aspects, the CESLs 1862, 1864 may include a hardmask material such as silicon nitride.

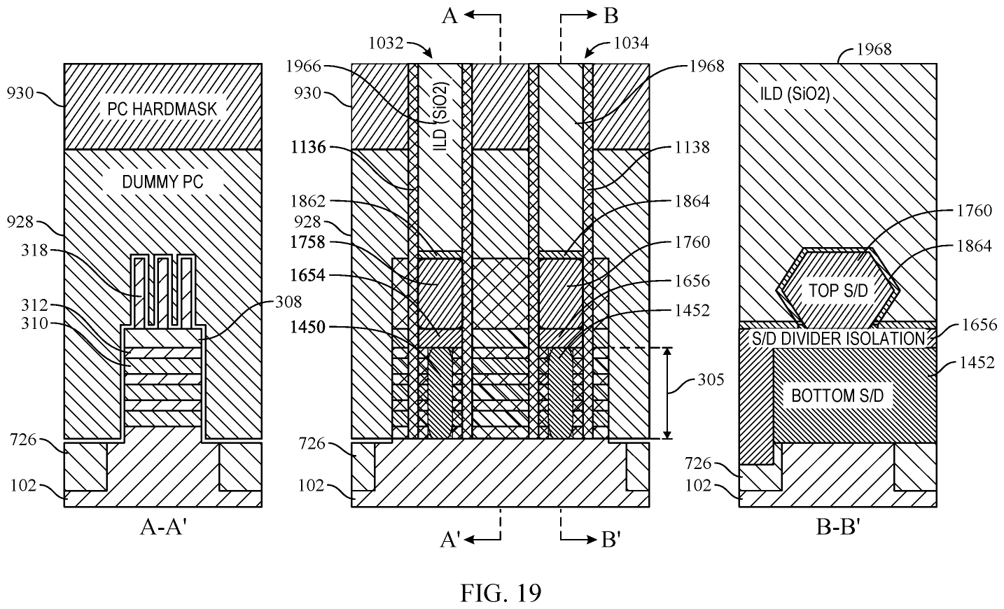

As shown in FIG. 19, third dielectric regions 1966, 1968 may be formed adjacent to the CESLs 1862, 1864 in the cavities 1032, 1034. In aspects, the third dielectric regions 1966, 1968 may fill the remaining portions of the cavities 1032, 1034 above the source and drain regions 1758, 1760. The third dielectric regions 1966, 1968 may be part of an inter-layer dielectric region that electrically isolates the source and drain regions 1758, 1760 from various electrical devices and/or electrical routing. A planarization process (e.g., a CMP process) may be performed to remove portions of the third dielectric regions 1966, 1968 disposed above the second hardmask layer 930.

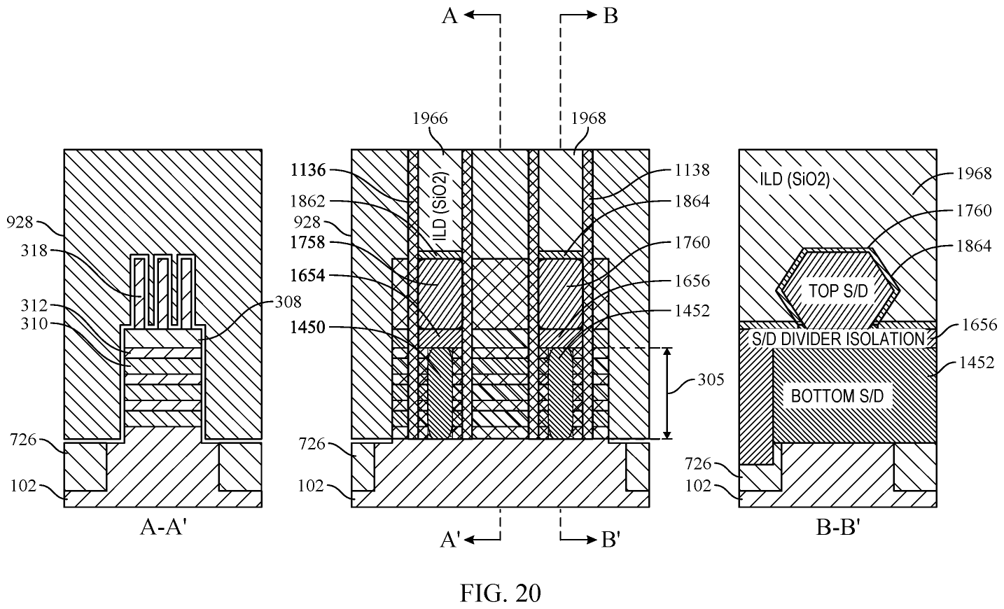

Referring to FIG. 20, the second hardmask layer 930 may be removed, for example, using a planarization process that may stop at the second dummy layer 928.

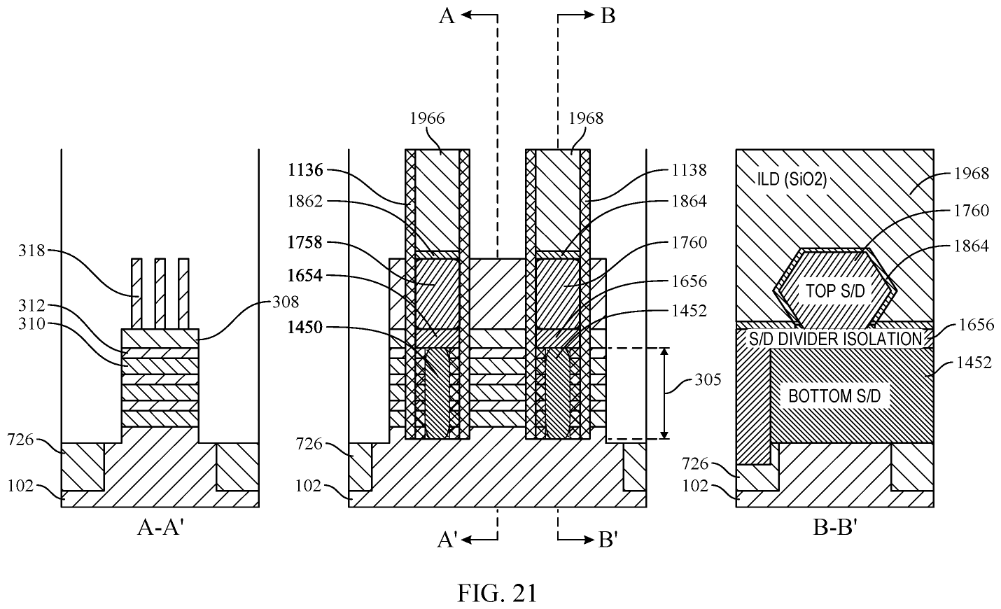

As illustrated in FIG. 21, the second dummy layer 928 may be removed, for example, using an etching process.

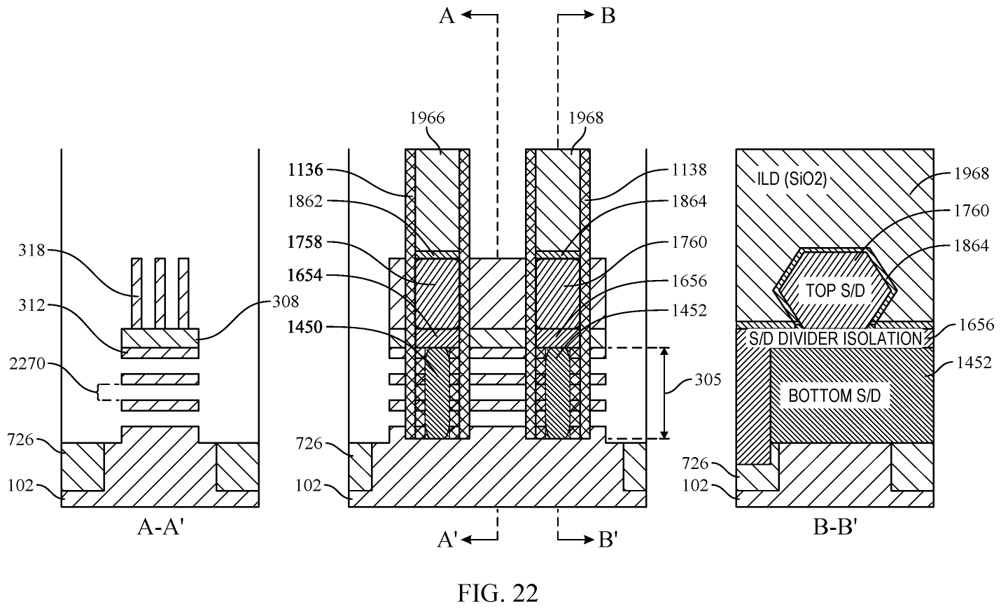

As depicted in FIG. 22, the layers of the first semiconductor material 310 are removed from the nanoslabs 305, for example, using an etching process. In aspects, separation areas 2270 may be formed between the layers of the second semiconductor material 312.

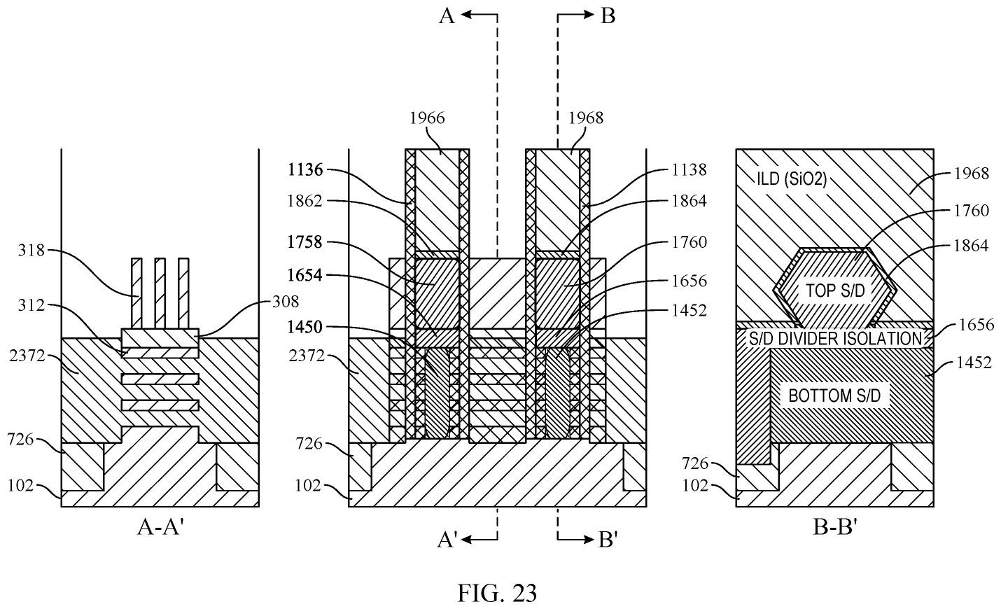

As shown in FIG. 23, a gate region 2372 for the NMOS transistor may be formed adjacent to the layers of the second semiconductor material 312. In aspects, a gate layer 2374 of the gate region 2372 may be formed in each of the separation areas 2270. In certain aspects, the gate region 2372 may correspond to the gate region 210 of FIG. 2.

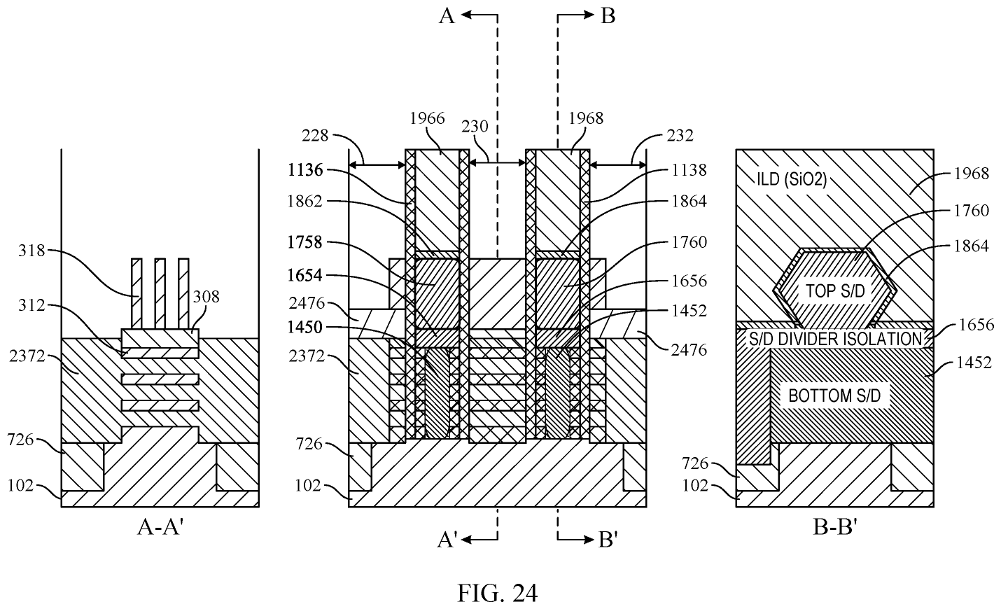

Referring to FIG. 24, in certain cases, one or more second dielectric layers 2476 are formed above the gate region 2372 of the first portion 228 and third portion 232. In aspects, the second dielectric layers 2476 may include a dielectric material such as silicon dioxide or silicon nitride. The second dielectric layers 2476 may provide electrical isolation between the gate regions on the sides of the transistors.

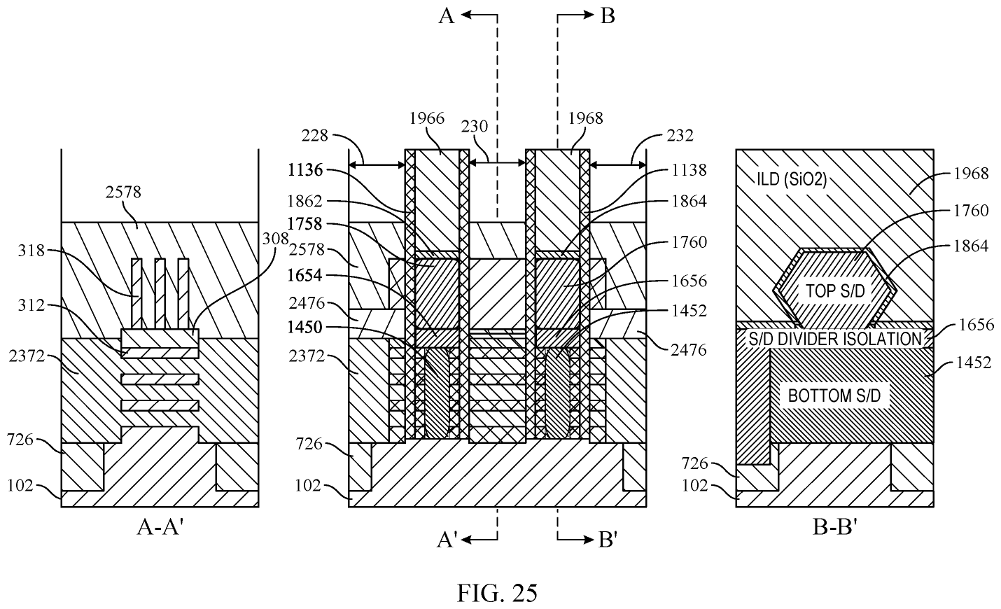

As illustrated in FIG. 25, a gate region 2578 for the PMOS transistor may be formed above the one or more second dielectric layers 2476 and above the gate region 2372 for the NMOS transistor. In aspects, the gate region 2578 may also be formed adjacent and between the semiconductor fin structures 318, for example, as depicted in the cross-section A-A′.

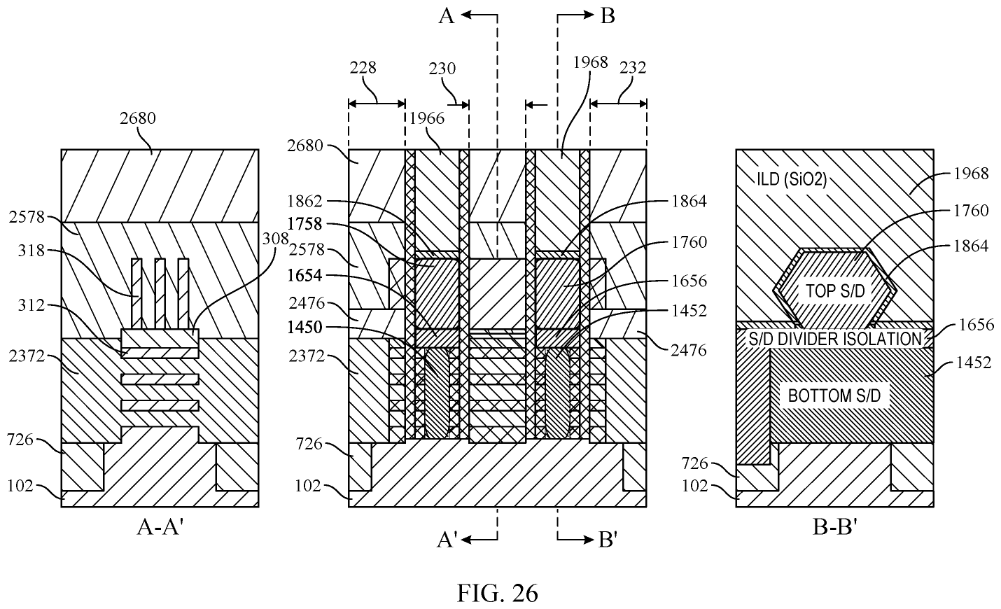

As depicted in FIG. 26, a third hardmask layer 2680 may be formed above the gate region 2578. In aspects, the third hardmask layer 2680 may include a hardmask material such as silicon nitride. The third hardmask layer 2680 may be a self-aligned contact and correspond to the third dielectric region 246 of FIG. 2.

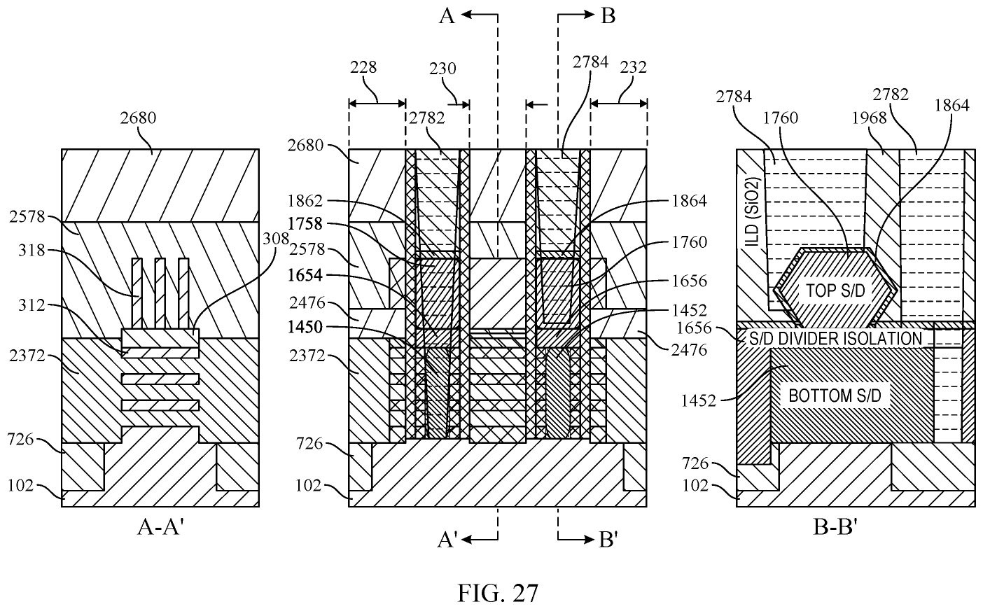

Referring to FIG. 27, terminals 2782, 2784 for the NMOS transistor and PMOS transistor, respectively, may be formed to electrically couple with the respective source and drain regions, for example, as described herein with respect to the terminals 240, 242 of FIG. 2.

FIGS. 28A-29C illustrate example operations for fabricating superlattice and semiconductor regions, in accordance with certain aspects of the present disclosure. The operations may be performed by a semiconductor fabrication facility, for example. In aspects, the superlattice and semiconductor regions may provide the base stack structure (such as the first stack structure 302) for forming transistors in the layered arrangement.

As shown in FIG. 28A, a stack structure 2802 may be formed above the substrate 102. The stack structure 802 may include a superlattice region 2804, a first semiconductor layer 2806, a second semiconductor layer 2808, and a hardmask layer 2810. In certain cases, the superlattice region 2804 is disposed above the substrate 102 and includes alternating layers of a first semiconductor material 2812 and layers of a second semiconductor material 2814. The NMOS transistor 104 may be formed from the superlattice region 2804. In aspects, the first semiconductor material 2812 may include silicon germanium (SiGe), and the second semiconductor material 2814 may include silicon (Si). In aspects, each of the layers of the first semiconductor material may be formed via a chemical vapor deposition (CVD) on an underlying layer of silicon, where the CVD produces a thin film of SiGe on the underlying silicon. In aspects, the various semiconductor layers of the stack structure 2802 may be epitaxially grown.

The first semiconductor layer 2806 is disposed above the superlattice region 2804 and may include silicon germanium. The second semiconductor layer 2808 is disposed above the first semiconductor layer 2806 and may include silicon. The hardmask layer 2810 is disposed above the second semiconductor layer 2808 and may include a hardmask material, such as silicon nitride.

Referring to FIG. 28B, first cavities 2816, 2818 may be formed through the stack structure 2802 and a portion of the substrate 102, for example, using an etching process. The cavities 2816, 2818 may serve as molds for semiconductor pillars, which may intersect the stack structure 2802 and the substrate 102.

As illustrated in FIG. 28C, semiconductor pillars 2820, 2822 may be formed in the cavities 2816, 2818. In aspects, the semiconductor pillars 2820, 2822 may include a semiconductor material such as silicon. The semiconductor pillars 2820, 2822 may support the second semiconductor layer 2808 and the hardmask layer 2810 in forming an STI region for the PMOS transistor as further described herein with respect to FIGS. 29B and 29C.

As shown in FIG. 29A, second cavities 2924, 2926, 2928 may be formed through the hardmask layer 2810, second semiconductor layer 2808, and a portion of the first semiconductor layer 2806. The second cavities 2924, 2926, 2928 may intersect the hardmask layer 2810 and second semiconductor layer 2808, such that a portion of the first semiconductor layer 2806 is exposed. In aspects, the second cavities 2924, 2926, 2928 may form a perimeter around the portions of the second semiconductor layer 2808 and hardmask layer 2810.

Referring to FIG. 29B, the first semiconductor layer 2806 may be removed from the stack structure 2802. That is, the second cavities 2924, 2926, 2928 may be expanded by removing the first semiconductor layer 2806. In certain aspects, the first semiconductor may be removed using a selective wet etching process for silicon germanium.

As illustrated in FIG. 29C, dielectric regions 2930, 2932, 2934 may be formed in the second cavities 2924, 2926, 2928, respectively. In aspects, the dielectric regions 2930, 2932, 2934 may form a perimeter around portions of the second semiconductor layer 2808 and hardmask layer 2810 providing an STI region around the second semiconductor layer 2808 and hardmask layer 2810. In aspects, semiconductor devices having an NMOS transistor and PMOS transistor in a layered arrangement may be formed between the semiconductor pillars. For example, a semiconductor device may be formed within the layered arrangement region 2936 as described herein with respect to FIGS. 3A-8B and 9-27.

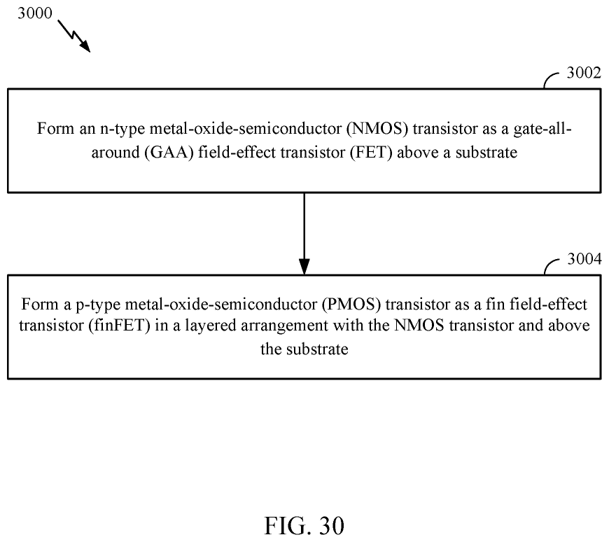

FIG. 30 is a flow diagram of example operations 3000 for fabricating a semiconductor device (e.g., the semiconductor device 100A, 100B, 200), in accordance with certain aspects of the present disclosure. The operations 3000 may be performed by a semiconductor fabrication facility, for example.

The operations 3000 begin at block 3002, by forming an NMOS transistor (e.g., the NMOS transistor 104) as a GAA FET above a substrate (e.g., the substrate 102). At 3004, a PMOS transistor (e.g., the PMOS transistor 106) may be formed as a finFET in a layered arrangement with the NMOS transistor and above the substrate.

In aspects, a base stack structure having various layers of semiconductors and dielectrics may be formed, for example, as described herein with respect to FIGS. 28A-29C. In aspects, the operations 3000 may further include forming a first stack structure (e.g., the stack structure 2802) comprising alternating layers of a first semiconductor material and a second semiconductor material above the substrate. One of the layers of the first semiconductor material (e.g., the first semiconductor layer 2806) may be removed from the first stack structure to form a separation area (e.g., the second cavities 2924, 2926, 2928) between a first portion of the first stack structure (e.g., the first portion 304 or the superlattice region 2804) and a second portion of the first stack structure (e.g., the second portion 306 or the second semiconductor layer 2808 and hardmask layer 2810). A dielectric layer (e.g., the first dielectric layer 308 or the dielectric regions 2930, 2932, 2934 or) in the separation area of the first stack structure. In aspects, forming the NMOS transistor at 3002 may include forming the NMOS transistor with the first portion of the first stack structure, and forming the PMOS transistor at 3004 may include forming the PMOS transistor with the second portion of the first stack structure, where the second portion of the first stack structure includes at least one layer of the second semiconductor material (e.g., the semiconductor layer 314 or second semiconductor layer 2808).

In aspects, forming the PMOS transistor at 3004 may include forming a semiconductor fin structure (e.g., the semiconductor fin structures 318) from the at least one layer of the second semiconductor material (e.g., the semiconductor layer 314).

In aspects, the source and drain regions of the NMOS and PMOS transistors may be formed in cavities in the base stack structure. For example, the first stack structure may be formed into a second stack structure (e.g., the second stack structure 1344), a third stack structure (e.g., the third stack structure 1346), and a fourth stack structure (e.g., fourth stack structure 1348). That is, the first stack structure may be segmented into the second stack structure, third stack structure, and fourth stack structure by forming cavities (e.g., the cavities 1032, 1034) that intersect the first stack structure. A source region (e.g., the source region 1450) of the NMOS transistor may be formed between the second stack structure and the third stack structure, and a drain region (e.g., the drain region 1452) of the NMOS transistor may be formed between the second stack structure and third stack structure. A dielectric region (e.g., the second dielectric regions 1654, 1656) may be formed above the source region and the drain region of the NMOS transistor. A source region (e.g., the source region 1758) of the PMOS transistor may be formed between the second stack structure and third stack structure and above the dielectric region, and a drain region (e.g., the drain region 1760) of the PMOS transistor may be formed between the third stack structure and fourth stack structure and above the dielectric region.

In aspects, the GAA transistor may be formed from a superlattice region of the base stack structure. In certain cases, the remaining layers of the first semiconductor material (e.g., the layers of the first semiconductor material 310) may be removed from the third stack structure to form other separation areas (e.g., the separation areas 2270) between the layers of the second semiconductor material (e.g., the layers of the second semiconductor material 312). A gate region (e.g., the gate region 2372) may be formed between the layers of the second semiconductor material, such that a gate layer (e.g., the gate layers 2374) is formed in each of the other separation areas.

Various electrical insulators (such as dielectric regions and/or dielectric layers including silicon dioxide or silicon nitride) may be formed between certain portions of the NMOS transistor and PMOS transistor. In aspects, a dielectric layer (e.g., the first dielectric layer 308) may be formed between the channel regions of the NMOS transistor and the channel regions of the PMOS transistor. In certain cases, a dielectric layer (e.g., the second dielectric layer 2476) may be formed between a gate region (e.g., the gate region 2372) of the NMOS transistor and a gate region (e.g., the gate region 2578) of the PMOS transistor. In aspects, one or more dielectric regions (e.g., the second dielectric regions 1654, 1656) may be formed between the source region or drain region of the NMOS transistor and the source region or drain region of the PMOS transistor.

In certain cases, the PMOS transistor may be formed above the NMOS transistor. In such a case, forming the NMOS transistor at 3002 may include forming a portion (e.g., the portion 236) of a source region or drain region of the NMOS transistor that extends beyond a surface (e.g., the surface 238) of a source region or a drain region of the PMOS transistor.

In certain cases, the NMOS transistor may be formed above the PMOS transistor. Forming the PMOS transistor at 3004 may include forming a portion of a source region of the PMOS transistor that extends beyond a surface of a source region or a drain region of the NMOS transistor.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A semiconductor device comprising:
a substrate;
an n-type metal-oxide-semiconductor (NMOS) transistor disposed above the substrate, the NMOS transistor being a gate-all-around (GAA) field-effect transistor (FET); and
a p-type metal-oxide-semiconductor (PMOS) transistor disposed above the substrate, the PMOS transistor being a fin field-effect transistor (finFET), wherein the PMOS transistor and the NMOS transistor are in a layered arrangement with each other.

2. The semiconductor device of claim 1, wherein the PMOS transistor comprises a semiconductor fin structure and a gate region surrounding a portion of the semiconductor fin structure.

3. The semiconductor device of claim 1, wherein the NMOS transistor comprises a gate region and a plurality of channel regions in a layered arrangement, wherein a portion of the gate region is disposed between each of the channel regions.

4. The semiconductor device of claim 3, wherein the gate region surrounds surfaces of the channel regions.

5. The semiconductor device of claim 1, further comprising a dielectric layer disposed between a channel region of the NMOS transistor and a channel region of PMOS transistor.

6. The semiconductor device of claim 1, further comprising a dielectric layer disposed between a gate region of the NMOS transistor and a gate region of the PMOS transistor.

7. The semiconductor device of claim 1, further comprising a dielectric region disposed between a source region of the NMOS transistor and a drain region or a source region of the PMOS transistor.

8. The semiconductor device of claim 1, wherein a gate region of the NMOS transistor is electrically coupled to a gate region of the PMOS transistor.

9. The semiconductor device of claim 1, wherein the PMOS transistor is in the layered arrangement disposed above the NMOS transistor.

10. The semiconductor device of claim 9, wherein a portion of a source region of the NMOS transistor extends beyond a surface of a source region or a drain region of the PMOS transistor.

11. The semiconductor device of claim 1, wherein the NMOS transistor is in the layered arrangement disposed above the PMOS transistor.

12. The semiconductor device of claim 11, wherein a portion of a source region of the PMOS transistor extends beyond a surface of a source region or a drain region of the NMOS transistor.

13. A method of fabricating a semiconductor device, comprising:
forming an n-type metal-oxide-semiconductor (NMOS) transistor as a gate-all-around (GAA) field-effect transistor (FET) above a substrate; and
forming a p-type metal-oxide-semiconductor (PMOS) transistor as a fin field-effect transistor (finFET) in a layered arrangement with the NMOS transistor and above the substrate.

14. The method of claim 13, further comprising:
forming a first stack structure comprising alternating layers of a first semiconductor material and a second semiconductor material above the substrate;
removing one of the layers of the first semiconductor material from the first stack structure to form a separation area between a first portion of the first stack structure and a second portion of the first stack structure; and
forming a dielectric layer in the separation area of the first stack structure, wherein:
forming the NMOS transistor comprises forming the NMOS transistor with the first portion of the first stack structure; and
forming the PMOS transistor comprises forming the PMOS transistor with the second portion of the first stack structure, the second portion of the first stack structure comprising at least one layer of the second semiconductor material.

15. The method of claim 14, wherein forming the PMOS transistor comprises forming a semiconductor fin structure from the at least one layer of the second semiconductor material.

16. The method of claim 14, further comprising:
forming, from the first stack structure, a second stack structure, a third stack structure, and a fourth stack structure;
forming a source region of the NMOS transistor between the second stack structure and the third stack structure;
forming a drain region of the NMOS transistor between the third stack structure and the fourth stack structure;
forming a dielectric region above the source region and the drain region of the NMOS transistor;
forming a source region of the PMOS transistor between the second stack structure and the third stack structure and above the dielectric region; and
forming a drain region of the PMOS transistor between the third stack structure and the fourth stack structure and above the dielectric region.

17. The method of claim 16, further comprising:
removing remaining layers of the first semiconductor material from the third stack structure to form other separation areas; and
forming a gate layer in each of the other separation areas.

18. The method of claim 13, further comprising forming a dielectric layer between a gate region of the NMOS transistor and a gate region of the PMOS transistor.

19. The method of claim 13, wherein forming the PMOS transistor comprises forming the PMOS transistor above the NMOS transistor.

20. The method of claim 19, wherein forming the NMOS transistor comprises forming a portion of a source region of the NMOS transistor that extends beyond a surface of a source region or a drain region of the PMOS transistor.
